(19) United States
(12) Patent Application Publication
(10) Pub. No.: US 2026/0277104 A1
(43) Pub. Date: Sep. 17, 2026

(54) NEGATIVE TYPE PHOTOSENSITIVE COMPOSITION

(71) Applicant: Merck Patent GmbH, Darmstadt (DE)

(72) Inventors: Akira Yamasaki, Shizuoka (JP); Atsuko Noya, Shizuoka (JP)

(21) Appl. No.: 19/480,120

(22) PCT Filed: Jun. 4, 2024
(86) PCT No.: PCT/EP2024/065241

§ 371 Date: Oct. 30, 2025

(30) Foreign Application Priority Data
Jun. 7, 2023 (JP) 2023-094211

(51) Int. Cl. G03F 7/075; G03F 7/40

(52) U.S. Cl. CPC G03F 7/0757; G03F 7/40

(57) ABSTRACT

[Problem] To provide a negative type photosensitive composition capable of being cured at a low temperature. [Means for Solution] A negative type photosensitive composition comprising (I) a polysiloxane A having a certain structure, (II) a polymerization initiator, (III) a compound containing two or more (meth)acryloyloxy groups, (IV) a thiol compound containing two or more sulfanyl groups, and (V) a solvent.

### BACKGROUND OF THE INVENTION

### Technical Field

The present invention relates to a negative type photosensitive composition. Further, the present invention relates to a method for manufacturing a cured film using the same, a cured film formed therefrom, and an electronic device comprising the cured film.

### Background Art

In recent years, various proposals have been made on optical devices such as displays, light-emitting diodes and solar cells for the purpose of improving light use efficiency and saving energy. For example, in a liquid crystal display, a method for increasing the aperture ratio of display devices, which comprises forming a transparent planarization film on a thin film transistor (hereinafter sometimes referred to as TFT) device to cover the device and forming a pixel electrode on the planarization film, is known.

A structure in which a touch panel is formed on an organic EL or liquid crystal module has been proposed. Furthermore, a flexible display using a plastic substrate instead of a glass substrate has attracted attention. In any case, it is desirable that the film formation on a device is performed at a lower temperature so that the constituent material of the device is not thermally degraded. In addition, when forming a coating on an organic semiconductor, an organic solar cell, or the like, capability to be cured at a lower temperature is required in consideration of the environment. However, for example, in the field of touch panels, as a panel reliability test, it is set as acceptance conditions that normal function can be achieved even if a constant voltage is applied for a certain period of time under high temperature and high humidity conditions. Therefore, it is known that ordinary acrylic polymer cures at a low temperature but many of them do not have the resistance and properties required by customers.

Polysiloxane is known for its high temperature resistance. When forming and curing a coating film using a composition comprising polysiloxane, it is required to lower the curing temperature depending on the constituent materials of the device. In general, in order to obtain a coating film having high temperature and high humidity resistance, it is necessary to heat the coating film at a high temperature to rapidly promote and complete the condensation reaction of a silanol group in the polysiloxane and the reaction of the polymer having an unsaturated bond. If unreacted reactive groups remain, they may react with chemicals used in the device manufacturing process. Various polysiloxane compositions that maintain chemical resistance and can be cured at a low temperature have been proposed (for example, Patent Document 1).

It has been proposed blending a thiol compound into a polysiloxane composition to improve its applicability on a substrate (for example, Patent Document 2).

### PRIOR ART DOCUMENTS

### Patent Documents

[Patent document 1] WO 2021/013859
[Patent document 2] WO 2009/113459

### SUMMARY OF THE INVENTION

### Problems to be Solved by the Invention

The present inventors have considered that there are one or more problems still need improvements in compositions comprising polysiloxane.

These include, for example, the followings: curing temperature is high; chemical resistance is low when curing temperature is made low; film shrinks when heated during curing; time required for curing is long; peeling due to film shrinkage occurs.

### Means for Solving the Problems

The negative type photosensitive composition according to the present invention comprises the following:
(I) a polysiloxane A comprising a repeating unit represented by the formula (Ia):

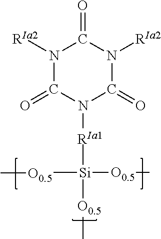

where
   R^{Ia1} is a C₁₋₅ alkylene group, where any of —CH₂— in the alkylene group can be replaced with —O—,
   R^{Ia2} is each independently hydrogen, a C₁₋₅ alkyl group or a C₁₋₅ alkylene group, where any of —CH₂— in the alkyl group and the alkylene group can be replaced with —O—, where when R^{Ia2} is an alkylene group, the bond that is not bonded to nitrogen is bonded to Si atoms contained in the polysiloxane A;
(II) a polymerization initiator;
(III) a compound containing two or more (meth)acryloyloxy groups;
(IV) a thiol compound containing two or more sulfanyl groups; and
(V) a solvent.

The method for manufacturing a cured film according to the present invention comprises applying the above-mentioned negative type photosensitive composition above a substrate to form a coating film, exposing the coating film to light and developing.

The cured film according to the present invention is manufactured by the above-mentioned method.

The electronic device according to the present invention comprises the above-mentioned cured film.

### Effects of the Invention

According to the present invention, one or more of the following effects can be desired:
curing temperature can be reduced; chemical resistance is sufficient even when curing at low temperature; film shrinkage can be suppressed when heated during curing; time required for curing is sufficiently short; peeling due to film shrinkage can be suppressed.

### DETAILED DESCRIPTION OF THE INVENTION

### Mode for Carrying Out the Invention

Embodiments of the present invention are described below in detail.

In the present specification, symbols, units, abbreviations, and terms have the following meanings unless otherwise specified.

In the present specification, unless otherwise specifically mentioned, the singular form includes the plural form and “one” or “that” means “at least one”. In the present specification, unless otherwise specifically mentioned, an element of a concept can be expressed by a plurality of species, and when the amount (for example, mass % or mol %) is described, it means sum of the plurality of species. “And/or” includes a combination of all elements and also includes single use of the element.

In the present specification, when a numerical range is indicated using “to” or “-”, it includes both endpoints and units thereof are common. For example, 5 to 25 mol % means 5 mol % or more and 25 mol % or less.

In the present specification, the hydrocarbon means one including carbon and hydrogen, and optionally including oxygen or nitrogen. The hydrocarbon group means a monovalent or divalent or higher valent hydrocarbon.

In the present specification, the aliphatic hydrocarbon means a linear, branched or cyclic aliphatic hydrocarbon, and the aliphatic hydrocarbon group means a monovalent or divalent or higher valent aliphatic hydrocarbon. The aromatic hydrocarbon means a hydrocarbon comprising an aromatic ring which may optionally not only comprise an aliphatic hydrocarbon group as a substituent but also be condensed with an alicycle. The aromatic hydrocarbon group means a monovalent or divalent or higher valent aromatic hydrocarbon. Further, the aromatic ring means a hydrocarbon comprising a conjugated unsaturated ring structure, and the alicycle means a hydrocarbon having a ring structure but comprising no conjugated unsaturated ring structure.

In the present specification, the alkyl means a group obtained by removing any one hydrogen from a linear or branched, saturated hydrocarbon and includes a linear alkyl and branched alkyl, and the cycloalkyl means a group obtained by removing one hydrogen from a saturated hydrocarbon comprising a cyclic structure and optionally includes a linear or branched alkyl in the cyclic structure as a side chain.

In the present specification, the aryl means a group obtained by removing any one hydrogen from an aromatic hydrocarbon. The alkylene means a group obtained by removing any two hydrogens from a linear or branched, saturated hydrocarbon. The arylene means a hydrocarbon group obtained by removing any two hydrogens from an aromatic hydrocarbon.

In the present specification, the descriptions such as “C_{x-y}”, “Cₓ-C_{y}” and “Cₓ” mean the number of carbons in the molecule or substituent group. For example, C₁₋₆ alkyl means alkyl having 1 to 6 carbons (such as methyl, ethyl, propyl, butyl, pentyl and hexyl). Further, the fluoroalkyl as used in the present specification refers to one in which one or more hydrogen in alkyl is replaced with fluorine, and the fluoroaryl is one in which one or more hydrogen in aryl are replaced with fluorine.

In the present specification, when polymer has a plural types of repeating units, these repeating units copolymerize. These copolymerization are any of alternating copolymerization, random copolymerization, block copolymerization, graft copolymerization, or a mixture of any of these.

In the present specification, “%” represents mass % and “ratio” represents ratio by mass.

In the present specification, Celsius is used as the temperature unit. For example, 20 degrees means 20 degrees Celsius.

In the present specification, polysiloxane means polymer including a bond of Si—O—Si (siloxane bond) as a main chain. Further, in the present specification, silsesquioxane polymer represented by the formula (RSiO_{1.5})ₙ shall also be included as the general polysiloxane.

### <Negative Type Photosensitive Composition>

The negative type photosensitive composition according to the present invention (hereinafter sometimes simply referred to as the composition) comprises (I) a polysiloxane A comprising a repeating unit represented by the formula (Ia) (hereinafter sometimes referred to as the component (I) and the same applies to other components), (II) a polymerization initiator, (III) a compound containing two or more (meth)acryloyloxy groups, (IV) a thiol compound containing two or more sulfanyl groups, and (V) a solvent. Hereinafter, each component contained in the composition according to the present invention is described in detail.

### (I) Polysiloxane A

The polysiloxane A used in the present invention comprises a repeating unit represented by the formula (Ia):

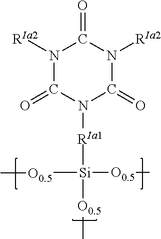

where
   R^{Ia1} is a C₁₋₅ alkylene group, where any —CH₂— in the alkylene group can be replaced with —O—, preferably not replaced with —O—. Examples of R^{Ia1} include a methylene group, an ethylene group and a propylene group, preferably a propylene group.
   R^{Ia2} is each independently hydrogen, a C₁₋₅ alkyl group or a C₁₋₅ alkylene group, where any —CH₂— in the alkyl group and the alkylene group can be replaced with —O—, preferably not replaced with —O—. When R^{Ia2} is an alkylene group, the bond that is not bonded to nitrogen is bonded to Si atoms contained in the polysiloxane A. When the alkyl group or the alkylene group contains —O—, the total number of carbon atoms and oxygen atoms is 1 to 5. Examples of R^{Ia2} include hydrogen, a methyl group, an ethyl group, a propyl group, a methylene group, an ethylene group and a propylene group, preferably a propyl group and a propylene group.

Two R^{Ia2} contained in one repeating unit can be identical or different, and it is preferable that at least one is an alkylene group. In other words, it is preferable that the isocyanurate ring has a structure in which two polysiloxane chains are crosslinked. More preferably, both of the two R^{Ia2} are alkylene groups, further more preferably, both of the two R^{Ia2} are propylene groups.

It is preferable that the polysiloxane A further comprises a repeating unit represented by the formula (Ib):

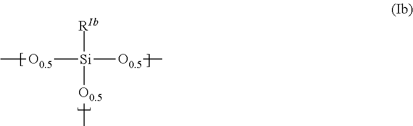

where
   R^{Ib} is hydrogen, a C₁₋₃₀ linear, branched or cyclic saturated aliphatic hydrocarbon group, or an aromatic hydrocarbon group.

Each of the aliphatic hydrocarbon group and the aromatic hydrocarbon group can be substituted with fluorine, hydroxy or alkoxy, provided that R^{Ib} is neither hydroxy nor alkoxy.

Any of —CH₂— in the aliphatic hydrocarbon group and the aromatic hydrocarbon group can be replaced with —O— or —CO—. The above-mentioned —CH₂— (methylene group) also includes the terminal methyl.

Further, the above phrase “can be substituted with fluorine, hydroxy or alkoxy” means that the hydrogen atom directly connected to a carbon atom in the aliphatic hydrocarbon group or the aromatic hydrocarbon group can be replaced with fluorine, hydroxy or alkoxy. In the present specification, the same applies to other similar descriptions.

Examples of R^{Ib} include (i) alkyl, such as methyl, ethyl, propyl, butyl, pentyl, hexyl, heptyl, octyl and decyl, (ii) aryl, such as phenyl, tolyl and benzyl, (iii) fluoroalkyl, such as trifluoromethyl, 2,2,2-trifluoroethyl, 3,3,3-trifluoropropyl, (iv) fluoroaryl, (v) cycloalkyl, such as cyclohexyl, (vi) an oxygen-containing group having an epoxy structure such as glycidyl, or an acryloyl structure or a methacryloyl structure. Preferably R^{Ib} is methyl, ethyl, propyl, butyl, pentyl, hexyl, phenyl, tolyl, glycidyl or isocyanate. When R^{Ib} is fluoroalkyl, R^{Ib} is preferably perfluoroalkyl, particularly preferably trifluoromethyl or pentafluoroethyl. It is preferable that R^{Ib} is methyl, because the raw material is easily available, the film hardness after curing is sufficiently high, and the chemical resistance is sufficiently high. Further, it is preferable that R^{Ib} is phenyl, because the solubility of the polysiloxane in the solvent is increased and the cured film is less likely to crack.

The polysiloxane A can further comprise a repeating unit represented by the formula (Ic):

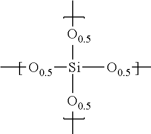

When the blending ratio of the repeating unit represented by the formula (Ic) is high, the photosensitivity of the composition decreases, the compatibility with solvents or additives decreases, and the film stress increases, so that cracks are likely to occur. For this reason, the content of the repeating unit represented by the formula (Ic) is preferably 40 mol % or less, more preferably 10 mol % or less, based on the total number of the repeating units of the polysiloxane A. In one preferable embodiment, the polysiloxane A does not contain the repeating units represented by the formula (Ic) (the content of the repeating unit (Id) is 0 mol %).

The polysiloxane A used in the present invention can further comprise a repeating unit represented by the formula (Id):

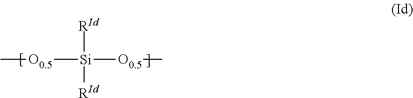

where
   R^{Id} each independently is hydrogen, a C₁₋₃₀ linear, branched or cyclic, saturated or unsaturated, aliphatic hydrocarbon group or an aromatic hydrocarbon group,
   the aliphatic hydrocarbon group and the aromatic hydrocarbon group can be substituted with fluorine, hydroxy or alkoxy, and
   —CH₂— in the aliphatic hydrocarbon group and the aromatic hydrocarbon group can be replaced with —O— or —CO—, provided that R^{Id} is neither hydroxy nor alkoxy.

Examples of R^{Id} include (i) alkyl, such as methyl, ethyl, propyl, butyl, pentyl, hexyl, heptyl, octyl and decyl, (ii) aryl, such as phenyl, tolyl and benzyl, (iii) fluoroalkyl, such as trifluoromethyl, 2,2,2-trifluoroethyl, 3,3,3-trifluoropropyl, (iv) fluoroaryl, (v) cycloalkyl, such as cyclohexyl, (vi) an oxygen-containing group having an epoxy structure, such as glycidyl, or an acryloyl structure or a methacryloyl structure. R^{Id} is preferably methyl, ethyl, propyl, butyl, pentyl, hexyl, phenyl, tolyl, glycidyl or isocyanate. When is fluoroalkyl, R^{Id} is preferably perfluoroalkyl, particularly preferably trifluoromethyl or pentafluoroethyl. It is preferable that R^{Id} is methyl, because the raw material is easily available, the film hardness after curing is sufficiently high, and the chemical resistance is sufficiently high. Further, it is preferable that R^{Id} is phenyl, because the solubility of the polysiloxane in the solvent is increased and the cured film is less likely to crack.

Through comprising the repeating unit represented by the above formula (Id), the polysiloxane can have a partially linear structure. However, since the heat resistance is reduced, it is preferable that the linear structure portion is small. In particular, the repeating unit represented by the formula (Id) is preferably 30 mol % or less, more preferably 10 mol % or less, based on the total number of the repeating units of the polysiloxane A. In one preferable embodiment, the polysiloxane A does not contain the repeating units represented by the formula (Id) (the content of the repeating unit (Id) is 0 mol %).

The polysiloxane A has a structure in which repeating units as mentioned above and blocks are bonded, but preferably has silanol at its terminal. Such a silanol group is obtained by bonding —O_{0.5}H to a bond of the above-mentioned repeating unit or block.

The number of the repeating units represented by the formula (Ia) contained in polysiloxane A is preferably larger for the better adhesion to the substrate. Further, in order to control the solubility in the developer, the number of the repeating units represented by the formula (Ia) contained in polysiloxane A is preferably smaller. In particular, the total number of Si atoms of the formula (Ia) contained in the polysiloxane A is preferably 1 to 15%, more preferably 2 to 5%, based on the total number of the Si atoms in the polysiloxane.

The mass average molecular weight of the polysiloxane A is not particularly limited.

On the other hand, the lower the molecular weight is, the less the synthesis conditions are limited and the easier the synthesis is, and it is difficult to synthesize a polysiloxane having a very high molecular weight. For these reasons, the mass average molecular weight of polysiloxane is usually 1,500 to 20,000, and preferably 2,000 to 15,000 in view of the solubility in an organic solvent and the solubility in an alkali developer. The mass average molecular weight is a mass average molecular weight in terms of polystyrene, which can be measured by the gel permeation chromatography based on polystyrene.

The component (I) can be one type or two or more types. The content of the component (I) is preferably 30 to 80 mass %, more preferably 40 to 80 mass %, further preferably 40 to 75% mass %, based on the total mass excluding the solvent contained in the composition.

### <Method for Synthesizing the Polysiloxane A>

The method for synthesizing the polysiloxane A used in the present invention is not particularly limited, but it can be obtained, for example, by hydrolyzing and polymerizing a silane monomer represented by the following formula (ia) optionally in the presence of an acidic catalyst or a basic catalyst:

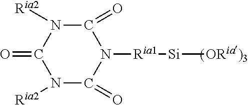

where
   R^{Ia2} is each independently hydrogen, an alkyl group having 1 to 5 carbon atoms, or —R^{ia1}—Si—(OR^{ia}′)₃, where —CH₂— in the alkyl group can be replaced with —O—,
   R^{ia1} is an alkylene group having 1 to 5 carbon atoms, where —CH₂— in the alkylene group can be replaced with —O—, and
   R^{ia}′ is each independently linear or branched C₁₋₆ alkyl.

Preferable R^{ia1} is the same as the preferable R^{Ia1} described above.

Preferable R^{ia}′ includes methyl, ethyl, n-propyl, isopropyl, n-butyl, and the like. In the formula (ia), a plurality of R^{ia}′ are contained, and each R^{ia}′ can be identical or different.

Preferable R^{Ia2} can be selected from those described as preferable in the above-mentioned R^{Ia2} and those described as preferable as the above-mentioned R^{ia1}.

Exemplified embodiments of the silane monomer represented by the formula (ia) include, for example, tris-(3-trimethoxysilylpropyl) isocyanurate, tris-(3-triethoxysilylpropyl) isocyanurate, tris-(3-tripropyloxysilylpropyl) isocyanurate, tris-(3-trimethoxysilylethyl) isocyanurate, tris-(3-triethoxysilylethyl) isocyanurate, tris-(3-tripropoxyoxysilylethyl) isocyanurate, tris-(3-trimethoxysilylmethyl) isocyanurate, tris-(3-triethoxysilylmethyl) isocyanurate, tris-(3-tripropoxysilylmethyl) isocyanurate, bis-(3-trimethoxysilylpropyl) methyl isocyanurate, bis-(3-triethoxysilylpropyl) methyl isocyanurate, bis-(3-tripropoxysilylpropyl) methyl isocyanurate, bis-(3-trimethoxysilylethyl) methyl isocyanurate, bis-(3-triethoxysilylethyl) methyl isocyanurate, bis-(3-tripropoxysilylethyl) methyl isocyanurate, bis-(3-trimethoxysilylmethyl) methyl isocyanurate, bis-(3-triethoxysilylmethyl) methyl isocyanurate, bis-(3-tripropoxysilylmethyl) methyl isocyanurate, 3-trimethoxysilylpropyl dimethyl isocyanurate, 3-triethoxysilylpropyl dimethyl isocyanurate, 3-tripropoxysilylpropyl dimethyl isocyanurate, 3-trimethoxysilylethyl dimethyl isocyanurate, 3-triethoxysilylethyl dimethyl isocyanurate, 3-tripropoxysilylethyl dimethyl isocyanurate, 3-trimethoxysilylmethyl dimethyl isocyanurate, 3-triethoxysilylmethyl dimethyl isocyanurate, and 3-tripropoxysilylmethyl dimethyl isocyanurate. Among them, tris-(3-trimethoxysilylpropyl) isocyanurate and tris-(3-triethoxysilylpropyl) isocyanurate are preferable.

Furthermore, it is preferable to combine a silane monomer represented by the formula (ib):

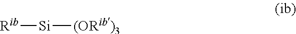

where
   R^{ib} is hydrogen, a C₁₋₃₀ linear, branched or cyclic, saturated or unsaturated, aliphatic hydrocarbon group or aromatic hydrocarbon group,
   the aliphatic hydrocarbon group and the aromatic hydrocarbon group can be substituted with fluorine, hydroxy or alkoxy, and
   —CH₂— in the aliphatic hydrocarbon group and the aromatic hydrocarbon group can be replaced with —O— or —CO—, provided that R^{ib} is neither hydroxy nor alkoxy, and
   R^{ib}′ is each independently linear or branched C₁₋₆ alkyl.

It is also preferable to combine two or more silane monomers represented by the formula (ib).

Preferable R^{ib} is the same as the preferable R^{Ib} described above.

Preferable R^{ib}′ includes methyl, ethyl, n-propyl, isopropyl, n-butyl, and the like. In the formula (ib), a plurality of R^{ib}′ are contained, and each R^{ib}′ can be identical or different.

Furthermore, a silane monomer represented by the following formula (ic) can be combined. When the silane monomer represented by the formula (ic) is used, polysiloxane containing the repeating unit (Ic) can be obtained.

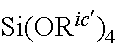

where
   R^{ic}′ is linear or branched C₁₋₆ alkyl.

In the formula (ic), preferable R^{ic}′ includes methyl, ethyl, n-propyl, isopropyl, n-butyl, and the like. In the formula (ic), a plurality of R^{ic}′ are contained, and each R^{ic}′ can be identical or different.

Exemplified embodiments of the silane monomer represented by the formula (ic) include tetramethoxysilane, tetraethoxysilane, tetraisopropoxysilane, tetra-n-butoxysilane, and the like.

Furthermore, a silane monomer represented by the following formula (id) can be combined. When the silane monomer represented by the formula (id) is used, polysiloxane containing the repeating unit (Id) can be obtained.

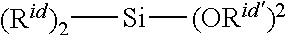

where
   R^{id}′ is each independently linear or branched C₁₋₆ alkyl, and examples thereof include methyl, ethyl, n-propyl, isopropyl, n-butyl, and the like. A plurality of R^{id}′ are contained in one monomer, and each R^{id}′ can be identical or different,
   R^{id} each independently is hydrogen, a C₁₋₃₀ linear, branched or cyclic, saturated or unsaturated, aliphatic hydrocarbon group or aromatic hydrocarbon group,
   the aliphatic hydrocarbon group and the aromatic hydrocarbon group can be substituted with fluorine, hydroxy or alkoxy, and
   —CH₂— in the aliphatic hydrocarbon group and the aromatic hydrocarbon group can be replaced with —O— or —CO—, provided that R^{id} is neither hydroxy nor alkoxy.

Preferable R^{id} is the same as the preferable R^{id} as described above.

The composition according to the present invention can further comprise a polymer different from the polysiloxane A. Examples of such a polymer include polysiloxane containing no repeating units of the formula (Ia), and acrylic resin. Preferably, in the composition according to the invention, the content of the polymer different from the polysiloxane A is 0 to 10 mass %, more preferably 0 to 5 mass %, based on the total mass of the component (I). In one preferable embodiment, the composition of the present invention contains no polymer different from the polysiloxane A (the content of the polymer different from the polysiloxane A is 0 mass %).

### (II) Polymerization Initiator

The composition according to the present invention comprises a polymerization initiator. These polymerization initiators include those that generate acids, bases or radicals when exposed to radiation, and those that generate acids, bases or radicals when exposed to heat. In the present invention, since the reaction starts immediately after radiation irradiation, and the reheating step that is performed after radiation irradiation and before the development step can be omitted, the polymerization initiators that generate acids, bases or radicals when exposed to radiation is preferable from the viewpoint of process reduction and cost, more preferably photo radical generators are preferable.

The photo radical generator can improve resolution by strengthening the pattern shape and increasing the contrast of development. The photo radical generator used in the present invention is a photo radical generator that releases radicals when irradiated with radiation. Examples of the radiation include visible light, ultraviolet ray, infrared ray, X-ray, electron beam, α-ray, γ-rays, or the like.

Examples of the photo radical generator include azo-based, peroxide-based, acylphosphine oxide-based, alkylphenone-based, oxime ester-based and titanocene-based initiators. Among them, alkylphenone-based, acylphosphine oxide-based and oxime ester-based initiators are preferable, including 2,2-dimethoxy-1,2-diphenylethan-1-one, 1-hydroxy-cyclohexylphenyl ketone, 2-hydroxy-2-methyl-1-phenylpropan-1-one, 1-[4-(2-hydroxyethoxy)phenyl]-2-hydroxy-2-methyl-1-propan-1-one, 2-hydroxy-1-{4-[4-(2-hydroxy-2-methylpropionyl)benzyl]phenyl}-2-methylpropan-1-one, 2-methyl-1-(4-methylthiophenyl)-2-morpholinopropan-1-one, 2-benzyl-2-dimethylamino-1-(4-morpholinophenyl)-1-butanone, 2-(dimethylamino)-2-[(4-methylphenyl)methyl]-1-[4-(4-morpholinyl)phenyl]-1-butanone, 2,4,6-trimethylbenzoyldiphenylphosphine oxide, bis(2,4,6-trimethylbenzoyl) phenylphosphine oxide, 1,2-octanedione, 1-[4-(phenylthio)-, 2-(0-benzoyloxime)], ethanone, 1-[9-ethyl-6-(2-methylbenzoyl)-9H-carbazol-3-yl]-, 1-(O-acetyloxime), and the like.

The component (II) can be one type or two or more types. The content of the component (II) is preferably 1.0 to 10.0 mass %, more preferably 1.5 to 8.0 mass %, based on the total mass of the component (1).

(III) Compound Containing Two or More (meth)acryloyloxy Groups

The composition according to the present invention comprises a compound containing two or more (meth)acryloyloxy groups (hereinafter sometimes referred to as the (meth)acryloyloxy group-containing compound for simplicity). The (meth)acryloyloxy group is a general term for the acryloyloxy group and the methacryloyloxy group. This compound is a compound that can form a crosslinked structure by reacting with an alkali-soluble resin or the like. In order to form a crosslinked structure, a compound containing two or more acryloyloxy groups or methacryloyloxy groups, which are reactive groups, is needed, and in order to form a higher-order crosslinked structure, it preferably contains three or more acryloyloxy groups or methacryloyloxy groups.

As the compound containing two or more (meth)acryloyloxy groups, esters obtained by reacting (α) a polyol compound having two or more hydroxyl groups with (β) two or more (meth)acrylic acids are preferably used. As the polyol compound (α), compounds having, as a basic skeleton, a saturated or unsaturated aliphatic hydrocarbon, aromatic hydrocarbon, heterocyclic hydrocarbon, primary, secondary or tertiary amine, ether or the like, and having, as substituents, two or more hydroxyl groups are included. The polyol compound can contain other substituent, for example, a carboxyl group, a carbonyl group, an amino group, an ether bond, a thiol group, a thioether bond, and the like, as long as the effects of the present invention are not impaired.

Preferable polyol compounds include alkyl polyols, aryl polyols, polyalkanolamines, cyanuric acid, and dipentaerythritol. When the polyol compound (α) has three or more hydroxyl groups, it is not necessary that all the hydroxyl groups have reacted with (meth)acrylic acid, and the hydroxyl groups can be partially esterified. This means that the esters can have unreacted hydroxyl group(s). As such esters, tris(2-acryloxyethyl) isocyanurate, dipentaerythritol hexa(meth)acrylate, tripentaerythritol octa(meth) acrylate, pentaerythritol tetra(meth)acrylate, dipropylene glycol diacrylate, tripropylene glycol diacrylate, trimethylolpropane triacrylate, polytetramethylene glycol dimethacrylate, trimethylolpropane trimethacrylate, ditrimethylolpropane tetraacrylate, tricyclodecane dimethanol diacrylate, 1,9-nonanediol diacrylate, 1,6-hexanediol diacrylate, 1,10-decanediol diacrylate, and the like are included. Among them, tris(2-acryloxyethyl) isocyanurate and dipentaerythritol hexaacrylate are preferable from the viewpoint of reactivity and the number of crosslinkable groups. Further, in order to adjust the shape of the formed pattern, two or more of these compounds can be combined. In particular, a compound containing three (meth)acryloyloxy groups and a compound containing two (meth)acryloyloxy groups can be combined.

The compound containing two or more (meth)acryloyloxy groups is preferably a molecule that is relatively smaller than the alkali-soluble resin from the viewpoint of reactivity. For this reason, the molecular weight of the compound containing two or more (meth)acryloyloxy groups is preferably 2,000 or less, and more preferably 1,500 or less.

The component (III) can be one type or two or more types. The content of the component (III) is adjusted depending on the type of polymer or (meth)acryloyloxy group-containing compound used, but is preferably 20 to 60 mass %, more preferably 25 to 55 mass %, based on the total mass of the component (I).

### (IV) Thiol Compound Containing Two or More Sulfanyl Groups

The composition according to the present invention comprises a thiol compound (IV) containing two or more sulfanyl groups.

By containing the component (IV), the composition according to the present invention can be cured at a low temperature and can suppress film shrinkage before and after curing the film. Furthermore, the cured film to be formed has sufficient chemical resistance. Although not to be bound by theory, it can be thought that the sulfanyl group and isocyanurate promote dehydration condensation of the polysiloxane A to form a crosslinked structure, and that the sulfanyl group is involved in the formation of the crosslinked bond in this process.

The component (IV) contains two or more sulfanyl groups (—SH), preferably 2 to 8, more preferably 2 to 6, and further preferably 3 or 4 sulfanyl groups.

The component (IV) can be a primary thiol compound or a secondary thiol compound, preferably a secondary thiol compound.

Examples of the primary thiol compound include ethylene glycol bis(3-mercaptopropionate), tris[(3-mercaptopropionyloxy)-ethyl]-isocyanurate, pentaerythritol tetrakis(3-mercaptopropionate), trimethylolpropane tris(3-mercaptopropionate), dipentaerythritol hexakis(3-mercaptopropionate), pentaerythritol tetrapropanethiol, 1,4-butanedithiol, 1,6-hexanedithiol, and the like.

Examples of the secondary thiol compound include pentaerythritol tetrakis(3-mercaptobutyrate), pentaerythritol tetrakis(2-mercaptobutyrate), dipentaerythritol hexakis(3-mercaptobutyrate), dipentaerythritol hexakis(2-mercaptobutyrate), trimethylolpropane tris(3-mercaptobutyrate), trimethylolpropane tris(2-mercaptobutyrate), 1,3,5-tris(2-(3-sulfanylbutanoyloxy)ethyl)-1,3,5-triazinane-2,4,6-trione, 1,4-bis(3-mercaptobutyryloxy)butane, trimethylolpropane tris(2-mercaptopropionate), ethylene glycol bis(2-mercaptopropionate), 2,3-butanedithiol, 2,5-hexanedithiol, and the like.

In a preferable embodiment, the component (IV) is a secondary thiol compound having two or more, preferably 2 to 8, more preferably 2 to 6, and further preferably 3 or 4 of the following structures.

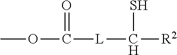

where L is a single bond or a C₁₋₅ alkylene group, and R² is a C₁₋₅ alkyl group.

The component (IV) is preferably selected from the group consisting of pentaerythritol tetrakis(3-mercaptobutyrate), trimethylolpropane tris(3-mercaptobutyrate), 1,3,5-tris(2-(3-sulfanylbutanoyloxy)ethyl)-1,3,5-triazinane-2,4,6-trione and 1,4-bis(3-mercaptobutyryloxy)butane.

The molecular weight of the component (IV) is not particularly limited, but is preferably 100 to 1,000, more preferably 100 to 900, further preferably 300 to 800.

The component (IV) can be one type or two or more types. The content of the component (IV) is preferably 0.5 to 30 mass %, more preferably 1 to 25 mass %, further preferably 1 to 20 mass %, based on the total mass of the component (I).

### (V) Solvent

The composition according to the present invention comprises a solvent. This solvent is not particularly limited as long as it can uniformly dissolve or disperse the above components and additives added as necessary. Examples of the solvent that can be used in the present invention include ethylene glycol monoalkyl ethers, such as ethylene glycol monomethyl ether, ethylene glycol monoethyl ether, ethylene glycol monopropyl ether and ethylene glycol monobutyl ether; diethylene glycol dialkyl ethers, such as diethylene glycol dimethyl ether, diethylene glycol diethyl ether, diethylene glycol dipropyl ether and diethylene glycol dibutyl ether; ethylene glycol alkyl ether acetates, such as methyl cellosolve acetate and ethyl cellosolve acetate; propylene glycol monoalkyl ethers, such as propylene glycol monomethyl ether (PGME) and propylene glycol monoethyl ether; propylene glycol alkyl ether acetates, such as propylene glycol monomethyl ether acetate (PGMEA), propylene glycol monoethyl ether acetate and propylene glycol monopropyl ether acetate; aromatic hydrocarbons, such as benzene, toluene and xylene; ketones, such as methyl ethyl ketone, acetone, methyl amyl ketone, methyl isobutyl ketone and cyclohexanone; alcohols, such as ethanol, propanol, butanol, hexanol, cyclohexanol, ethylene glycol and glycerin; esters, such as ethyl lactate, ethyl 3-ethoxypropionate, methyl 3-methoxypropionate; and cyclic esters, such as γ-butyrolactone, and the like. The component (V) is preferably PGMEA, PGME or a mixture thereof.

The content of component (V) can be optionally adjusted depending on the method for applying the composition, etc. The content of the component (V) is preferably 50 to 90 mass %, more preferably 50 to 80 mass %, based on the total mass of the composition.

### (VI) Surfactant

The composition according to the present invention can further comprise a surfactant. The surfactant is added for the purpose of improving coating properties, developability, and the like. Examples of the surfactant that can be used in the present invention include nonionic surfactants, anionic surfactants and amphoteric surfactants.

Examples of the nonionic surfactant include, polyoxyethylene alkyl ethers, such as polyoxyethylene lauryl ether, polyoxyethylene oleyl ether and polyoxyethylene cetyl ether; polyoxyethylene fatty acid diester; polyoxyethylene fatty acid monoester; polyoxyethylene polyoxypropylene block polymer; acetylene alcohol; acetylene glycol; polyethoxylate of acetylene alcohol; acetylene glycol derivatives, such as polyethoxylate of acetylene glycol; fluorine-containing surfactants, such as Fluorad (trade name, 3M Japan Limited), Megafac (trade name, DIC Corporation), Surflon (trade name, AGC Inc.); or organosiloxane surfactants, such as KP341 (trade name, Shin-Etsu Chemical Co., Ltd.). Examples of the above-mentioned acetylene glycol include 3-methyl-1-butyne-3-ol, 3-methyl-1-pentyn-3-ol, 3,6-dimethyl-4-octyne-3,6-diol, 2,4,7,9-tetramethyl-5-decyne-4,7-diol, 3,5-dimethyl-1-hexyne-3-ol, 2,5-dimethyl-3-hexyne-2,5-diol, 2,5-di-methyl-2,5-hexanediol, and the like.

Examples of the anionic surfactant include ammonium salt or organic amine salt of alkyl diphenyl ether disulfonic acid, ammonium salt or organic amine salt of alkyl diphenyl ether sulfonic acid, ammonium salt or organic amine salt of alkyl benzene sulfonic acid, ammonium salt or organic amine salt of polyoxyethylene alkyl ether sulfuric acid, ammonium salt or organic amine salt of alkyl sulfuric acid, and the like.

Examples of the amphoteric surfactant include 2-alkyl-N-carboxymethyl-N-hydroxyethyl imidazolium betaine, lauric acid amide propyl hydroxysulfone betaine, and the like.

The component (VI) can be one type or two or more types. The content of the component (VI) is preferably 0.0001 to 0.05 mass %, more preferably 0.0005 to 0.01 mass %, based on the total mass of the composition.

In the composition according to the present invention, additives can be combined besides the above-mentioned (I) to (VI), if necessary. The content of other than (I) to (VI) is preferably 0 to 10 mass %, more preferably 0 to 5 mass %, further preferably 0 to 1 mass %, based on the total mass of the composition. It is also one embodiment of the present invention that components other than (I) to (VI) are not contained.

Examples of the additive include developer solubility promoters, scum removers, adhesion enhancers, polymerization inhibitors, antifoaming agents, sensitizers, and the like.

### <Method for Forming Cured Film>

The method for forming a cured film according to the present invention comprises applying the above-mentioned composition above a substrate to form a coating film, exposing the coating film, and developing the coating film. The method for forming a cured film is described in process order as follows.

### (1) Application Process

First, the above-mentioned composition is applied above a substrate. Formation of the coating film of the composition in the present invention can be carried out by any method conventionally known as a method for applying a photosensitive composition. In particular, it can be optionally selected from dip coating, roll coating, bar coating, brush coating, spray coating, doctor coating, flow coating, spin coating, slit coating, and the like. Further, as the substrate on which the composition is applied, a suitable substrate such as a silicon substrate, a glass substrate, a resin film, and the like can be used. Various semiconductor devices and the like can be formed on these substrates as needed. When the substrate is a film, gravure coating can also be utilized. If desired, a drying process can be additionally provided after applying the film. Further, if necessary, the applying process can be repeated once or twice or more to make the film thickness of the coating film to be formed as desired.

### (2) Pre-Baking Process

After forming the coating film of the composition by applying the composition, it is preferable to carry out pre-baking (heat treatment) of the coating film in order to dry the coating film and reduce the residual amount of the solvent in the coating film. The pre-baking process can be carried out at a temperature of generally 50 to 150° C., preferably 70 to 120° C., in the case of a hot plate, for 10 to 300 seconds, preferably 30 to 120 seconds and in the case of a clean oven, for 1 to 30 minutes.

### (3) Exposure Process

After forming a coating film, the coating film surface is then irradiated with light. As the light source to be used for the light irradiation, any one conventionally used for a pattern forming method can be used. As such a light source, a high-pressure mercury lamp, a low-pressure mercury lamp, a lamp such as metal halide and xenon, a laser diode, an LED and the like can be included. As the irradiation light, ultraviolet ray such as g-line, h-line and i-line is usually used. Preferably, the exposure is performed using the irradiation light with a peak wavelength of 360 to 440 nm. Among these, the light with a peak wavelength of 430 nm is often used for liquid crystal display devices. In such cases, as mentioned above, it is advantageous to combine the composition according to the present invention with a sensitizing dye. The energy of the irradiated light depends on the light source and the film thickness of the coating film, but is generally 5 to 2,000 mJ/cm², preferably 10 to 1,000 mJ/cm². If the irradiation light energy is lower than 5 mJ/cm², sufficient resolution may not be obtained; on the other hand, if it is higher than 2,000 mJ/cm², the exposure becomes excess and occurrence of halation is sometimes brought.

In order to irradiate light in a pattern shape, a general photomask can be used. Such a photomask can be optionally selected from well-known ones. The environment at the time of irradiation is not particularly limited and can generally be set as an ambient atmosphere (in the air) or nitrogen atmosphere. Further, in the case of forming a film on the entire surface of the substrate, light irradiation can be performed over the entire surface of the substrate. In the present invention, the pattern film also includes such a case where a film is formed on the entire surface of the substrate.

### (4) Post Exposure Baking Process

After the exposure, to promote the reaction between the polymer in the film by the polymerization initiator, post exposure baking can be performed as necessary. Different from the heating process (6) to be described later, this heating treatment is performed not to completely cure the coating film but to leave only a desired pattern on the substrate after development and to make other areas capable of being removed by development. Therefore, it is not essential in the present invention.

When the post exposure baking is performed, a hot plate, an oven, a furnace, and the like can be used. The heating temperature should not be excessively high because it is not desirable for the acid, base or radical in the exposed area, which is generated by light irradiation, to diffuse to the unexposed area. From such a viewpoint, the range of the heating temperature after exposure is preferably 40 to 150° C., and more preferably 60 to 120° C. Stepwise heating can be applied as needed to control the curing rate of the composition. Further, the atmosphere during the heating is not particularly limited and can be selected from in an inert gas such as nitrogen, under a vacuum, under a reduced pressure, in an oxygen gas, and the like, for the purpose of controlling the curing rate of the composition. Further, the heating time is preferably above a certain level in order to maintain higher the uniformity of temperature history in the wafer surface and is preferably not excessively long in order to suppress diffusion of the generated acid, base or radical. From such a viewpoint, the heating time is preferably 20 seconds to 500 seconds, and more preferably 40 seconds to 300 seconds.

### (5) Developing Process

After post exposure heating is optionally performed after exposure, the coating film is developed. As the developer to be used at the time of development, any developer conventionally used for developing a photosensitive composition can be used. In the present invention, a TMAH aqueous solution is used to specify the dissolution rate of alkali-soluble resin, but the developer used for forming the cured film is not limited to this. Preferable examples of the developer include an alkali developer which is an aqueous solution of an alkaline compound such as tetraalkylammonium hydroxide, choline, alkali metal hydroxide, alkali metal metasilicate (hydrate), alkali metal phosphate (hydrate), ammonia, alkylamine, alkanolamine and heterocyclic amine, and a particularly preferable alkali developer is a TMAH aqueous solution, a potassium hydroxide aqueous solution, or a sodium hydroxide aqueous solution. In this alkali developer, a water-soluble organic solvent such as methanol and ethanol, or a surfactant can be further contained, if necessary. The developing method can also be optionally selected from conventionally known methods. In particular, methods such as immersing (dipping) in a developer, paddle, shower, slit, cap coat, spray, and the like can be included. After the development with a developer, by which a pattern can be obtained, it is preferable that rinsing with water is carried out.

### (6) Heating Process

After development, the obtained pattern film is cured by heating. The method for forming a cured film according to the present invention further comprises a process of heating at a temperature of 70 to 110° C. As the heating apparatus used for the heating process, the same one as used for the above-mentioned post exposure baking can be used. The heating temperature in the heating process is not particularly limited as long as it is a temperature at which curing of the coating film can be performed and can be optionally determined. However, if the silanol group remains, the chemical resistance of the cured film sometimes becomes insufficient, or dielectric constant of the cured film sometimes becomes higher. From such a viewpoint, a relatively high temperature is generally selected as the heating temperature. In order to keep the remaining film ratio after curing high, the curing temperature is more preferably 350° C. or lower, and particularly preferably 250° C. or lower. On the other hand, in order to accelerate the curing reaction and obtain a sufficiently cured film, the curing temperature is preferably 70° C. or higher, more preferably 80° C. or higher, and particularly preferably 90° C. or higher. However, the composition according to the present invention retains sufficient chemical resistance even when cured at a low temperature of 70 to 110° C. Further, the heating time is not particularly limited and is generally 10 minutes to 24 hours, and preferably 30 minutes to 3 hours. This heating time is a time from when the temperature of the pattern film reaches a desired heating temperature. It takes about several minutes to several hours for the pattern film to reach a desired temperature from the temperature before heating.

The cured film thus obtained has suppressed film shrinkage and sufficient chemical resistance. Furthermore, sufficient transparency, environmental resistance, and the like can be achieved. For example, a film cured at 100° C. can achieve a light transmittance of 95% or more and also the relative dielectric constant of 4 or less. For this reason, the cured film has light transmittance, relative dielectric constant, chemical resistance and environmental resistance, which are not available with the conventionally used acrylic material, and therefore the cure film can be suitably utilized in many fields as a planarization film for the above-mentioned various devices such as a flat panel display (FPD), an interlayer insulating film for low temperature polysilicon or a buffer coat film for IC chip, a transparent protective film, and the like.

The present invention is explained more particularly below with reference to Examples and Comparative Examples, but the present invention is not limited by these Examples and Comparative Examples at all.

The mass average molecular weight (Mw) is measured by the gel permeation chromatography (GPC) based on polystyrene. GPC is measured using an Alliance™ e2695 type high-speed GPC system (Nihon Waters) and a Super Multipore HZ—N type GPC column (Tosoh). After the measurement is carried out using monodisperse polystyrene as a standard sample and tetrahydrofuran as a developing solvent under the measurement conditions of a flow rate of 0.6 ml/min and a column temperature of 40° C., Mw is calculated as the relative molecular weight to the standard sample.

### Synthesis Example 1: Polysiloxane A1

In a 1 L three-neck flask equipped with a stirrer, thermometer and condenser, 8 g of a 35 mass % HCl aqueous solution, 400 g of PGMEA and 27 g of water are charged, and then a mixed solution of 39.7 g of phenyltrimethoxysilane, 34.1 g of methyltrimethoxysilane, 30.8 g of tris-(3-trimethoxysilylpropyl) isocyanurate and 0.3 g of trimethoxysilane is prepared. The mixed solution is added dropwise into the flask at 10° C. and stirred at the same temperature for 3 hours. Next, 300 g of propyl acetate is added to separate into an oil layer and an aqueous layer using a separating funnel. In order to further remove the sodium remaining in the oil layer after separation, the oil layer is washed four times with 200 g of water, and the pH of the waste liquid in water tank is confirmed to be 4 to 5. The obtained organic layer is concentrated under reduced pressure to remove the solvent, and PGMEA is added to the concentrate to adjust the solid content concentration to 50 mass %, thereby obtaining the polysiloxane A1 solution. The Mw of the obtained polysiloxane A1 is 11,200.

### Synthesis Example 2: Polysiloxane B1

In a 2 L flask equipped with a stirrer, thermometer and condenser, 29.1 g of methyltrimethoxysilane, 0.6 g of phenyltrimethoxysilane, 0.4 g of tetramethoxysilane and 308 ml of PGME are charged, and the resultant mixture is cooled to 0.2° C. Next, from a dropping funnel, 96.6 g of a 37 mass % tetra-n-butylammonium hydroxide methanol solution is added dropwise into the flask and the resultant mixture is stirred for 2 hours. Thereafter, 500 ml of n-propyl acetate is added, and the resultant mixture is cooled to 0.2° C. again, and after adding 3 mass % hydrochloric acid aqueous solution, which is 1.1 equivalents with respect to TBAH, the mixture is stirred for 1 hour to be neutralized. To the neutralized liquid, 1,000 ml of normal propyl acetate and 250 ml of water are added to separate the reaction liquid into two layers, and the resulting organic layer is washed three times with 250 cc of water, and water and the solvent are removed by concentrating under reduced pressure. Then, PGMEA is added to the concentrate to adjust the solid content concentration to 50 mass %, thereby obtaining the polysiloxane B1 solution. The Mw of the obtained polysiloxane B1 is 2,850.

### Preparation of Compositions of Examples 1 to 12 and Comparative Examples 1 to 4

The compositions of Examples 1 to 12 and Comparative Examples 1 to 4 are prepared so that the compositions excluding the solvent have the components and contents shown in Tables 1 and 2 below. In the tables, numerical values of the composition are the mass % of each component based on the total mass of the composition excluding the solvent. As the solvent, a mixed solvent of PGMEA/PGME (35 mass %/65 mass %) is used, and the content is 70 mass % based on the total mass of the composition.

TABLE 1

| | | | Example | | | | | | | |
|---|---|---|---|---|---|---|---|---|---|---|
| | | | 1 | 2 | 3 | 4 | 5 | 6 | 7 | 8 |
| Composition | (I) | Polysiloxane A1 | 100 | 100 | 100 | 100 | 100 | 100 | 100 | 100 |
| | Polysiloxane B1 | | — | — | — | — | — | — | — | — |
| | (II) | Polymerization | 3.5 | 3.5 | 3.5 | 3.5 | 3.5 | 3.5 | 3.5 | 3.5 |
| | | initiator A | | | | | | | | |
| | (III) | AM-1 | 40 | — | — | 40 | — | — | 40 | — |
| | | AM-2 | — | 40 | — | — | 40 | — | — | 40 |
| | | AM-3 | — | — | 40 | — | — | 40 | — | — |
| | (IV) | SM-1 | 5 | 10 | 15 | — | — | — | — | — |
| | | SM-2 | — | — | — | 10 | 3 | 18 | — | — |
| | | SM-3 | — | — | — | — | — | — | 17 | 2 |
| | | SM-4 | — | — | — | — | — | — | — | — |

| | | | | | | | | | |
|---|---|---|---|---|---|---|---|---|---|
| | Surfactant A | 0 | 0 | 0 | 0 | 0 | 0 | 0 | 0 |
| Evaluation | Film shrinkage rate | A | A | A | A | A | A | A | A |
| | | 8% | 5% | 5% | 5% | 7% | 6% | 5% | 9% |
| | Chemical resistance | A | A | A | A | A | A | A | A |

| | | | | | | | |
|---|---|---|---|---|---|---|---|
| 5% | 3% | 5% | 7% | 5% | 5% | 6% | 5% |

TABLE 2

| | | | Example | | | | Coparative Example | | | |
|---|---|---|---|---|---|---|---|---|---|---|
| | | | 9 | 10 | 11 | 12 | 1 | 2 | 3 | 4 |
| Composition | (I) | Polysiloxane A1 | 100 | 100 | 100 | 100 | 100 | 100 | 100 | — |
| | Polysiloxane B1 | | — | — | — | — | — | — | — | 100 |
| | (II) | Polymerization | 3.5 | 3.5 | 3.5 | 3.5 | 3.5 | 3.5 | 3.5 | 3.5 |
| | | initiator A | | | | | | | | |
| | (III) | AM-1 | — | 40 | — | — | 40 | — | — | 40 |
| | | AM-2 | — | — | 40 | — | — | 40 | — | — |
| | | AM-3 | 40 | — | — | 40 | — | — | 40 | — |
| | (IV) | SM-1 | — | — | — | — | — | — | — | 10 |
| | | SM-2 | — | — | — | — | — | — | — | — |
| | | SM-3 | 10 | — | — | — | — | — | — | — |
| | | SM-4 | — | 10 | 15 | 5 | — | — | — | — |

| | | | | | | | | | |
|---|---|---|---|---|---|---|---|---|---|
| | Surfactant A | 0 | 0 | 0 | 0 | 0 | 0 | 0 | 0 |
| Evaluation | Film shrinkage rate | A | A | A | A | B | B | B | B |
| | | 8% | 8% | 5% | 10% | 12% | 12% | 15% | 16% |
| | Chemical resistance | A | A | A | A | B | B | B | C |

| | | | | | | | |
|---|---|---|---|---|---|---|---|
| 7% | 7% | 3% | 8% | 10% | 9% | 11% | 24% |

In the tables:
polymerization initiator A: “IRGACURE OXE-02”, BASF Japan;
AM-1: dipentaerythritol hexaacrylate;
AM-2: ε-caprolactone modified tris-(2-acryloxyethyl) isocyanurate “A-9300-1GCL”, Shin-Nakamura Chemical;
AM-3: glycerin triacrylate;
SM-1: pentaerythritol tetrakis(3-mercaptobutyrate);
SM-2: TrimethyloIpropane tris(3-mercaptobutyrate);
SM-3: 1,3,5-tris(2-(3-sulfanylbutanoyloxy)ethyl)-1,3,5-triazinane-2,4,6-trione;
SM-4: 1,4-bis(3-mercaptobutyryloxy) butane; and
surfactant A: “AKS-10”, Shin-Etsu Chemical.

### <Film Shrinkage Rate>

The obtained compositions are respectively applied on 4-inch Si wafers using a spin coater (1HDX2, Mikasa) at 1,000 rpm. The coated substrates are respectively prebaked for 90 seconds on a hot plate heated to 80° C. The film thickness after prebaking is respectively measured using a spectroscopic ellipsometer “M-2000V” (J. A. Woollam). The prebaked films are further respectively heated in an oven at 80° C. for 60 minutes in an air atmosphere to form cured films. The film thickness of the cured films are measured using the spectroscopic ellipsometer. The film shrinkage rates are respectively calculated using the following formula:

Film shrinkage rate (%)=(film thickness after prebaking−film thickness of cured film)/film thickness after prebaking×100

The calculated film shrinkage rates are respectively evaluated according to the following criteria:
A: film shrinkage rate is within 10%
B: film shrinkage rate exceeds 10%

### <Chemical Resistance>

The obtained compositions are respectively applied on 4-inch Si wafers using a spin coater at 1,000 rpm. The coated substrates are respectively prebaked for 90 seconds on a hot plate heated to 80° C., and then respectively heated in an oven at 80° C. for 60 minutes in an air atmosphere to form cured films. The film thickness of the cured films are measured using a spectroscopic ellipsometer.

The cured films are respectively immersed in solutions composed of dimethyl sulfoxide: monoethanolamine=30: 70 (mass ratio) at 60° C. for 3 minutes. The film thickness after immersion is measured respectively using the spectroscopic ellipsometer. The chemical resistance is respectively calculated using the following formula:

Chemical resistance (%)=(film thickness of cured film−film thickness after immersion)/film thickness of cured film×100

The calculated chemical resistance is respectively evaluated according to the following criteria:
A: chemical resistance is within 8%
B: chemical resistance exceeds 8% and within 12%
C: chemical resistance exceeds 12%

1. A negative type photosensitive composition comprising the following:
(I) a polysiloxane A comprising a repeating unit represented by the formula (Ia): 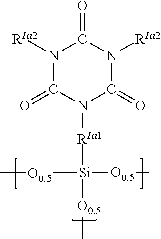
where
R^{Ia1} is a C₁₋₅ alkylene group, where any of —CH₂— in the alkylene group can be replaced with —O—,
R^{Ia2} is each independently hydrogen, a C₁₋₅ alkyl group or a C₁₋₅ alkylene group, where any of —CH₂— in the alkyl group and the alkylene group can be replaced with —O—, where when R^{Ia2} is an alkylene group, the bond that is not bonded to nitrogen is bonded to Si atoms contained in the polysiloxane A;
(II) a polymerization initiator;
(III) a compound containing two or more (meth)acryloyloxy groups;
(IV) a thiol compound containing two or more sulfanyl groups; and
(V) a solvent.

2. The composition according to claim 1, wherein the polysiloxane A further comprises a repeating unit represented by the formula (Ib): 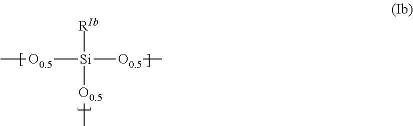
where
R^{Ib} is hydrogen, a C₁₋₃₀ linear, branched or cyclic saturated aliphatic hydrocarbon group, or an aromatic hydrocarbon group, each of the aliphatic hydrocarbon group and the aromatic hydrocarbon group can be substituted with fluorine, hydroxy or alkoxy, and any of —CH₂— in the aliphatic hydrocarbon group and the aromatic hydrocarbon group can be replaced with —O— or —CO—.

3. The composition according to claim 1, wherein the total number of Si atoms in the formula (Ia) contained in the polysiloxane A is 1 to 15% based on the total number of Si atoms in the polysiloxane A.

4. The composition according to claim 1, wherein the thiol compound is a secondary thiol compound.

5. The composition according to claim 1, wherein the content of the thiol compound is 0.5 to 30 mass % based on the total mass of the polysiloxane A.

6. The composition according to claim 1, wherein the content of the polysiloxane A is 30 to 80 mass % based on the total mass excluding the solvent contained in the composition.

7. A method for manufacturing a cured film, comprising applying the composition according to claim 1 above a substrate to form a coating film, exposing the coating film to light and developing.

8. The method according to claim 7, wherein the exposure is performed using the irradiation light with a peak wavelength of 360 to 440 nm.

9. The method according to claim 7, further comprising a step of heating at a temperature of 70 to 110° C. after development.

10. A cured film formed by the method according to claim 7.

11. An electronic device comprising the cured film according to claim 10.
